(19) United States
(12) Patent Application Publication
(10) Pub. No.: US 2009/0256256 A1
(43) Pub. Date: Oct. 15, 2009

(54) Electronic Device and Method of Manufacturing Same

(75) Inventor: Thorsten MEYER, Regensburg (DE)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Neubiberg (DE)

(21) Appl. No.: 12/101,170

(22) Filed: Apr. 11, 2008

(51) Int. Cl. H01L 23/52

(52) U.S. Cl. 257/738; 257/E23.141

(57) ABSTRACT

This application relates to a semiconductor device comprising an array of contact elements soldered to only one surface, wherein the array defines a predetermined pitch length, wherein the contact elements comprise a spherically shaped element and wherein the contact elements protrude from the only one surface by more than 60 percent of the predetermined pitch.

### BACKGROUND

The present invention relates to a semiconductor device and methods of manufacturing semiconductor devices.

In the wake of increasing levels of function integration in semiconductor devices, the number of input/output channels of semiconductor devices has been rising continuously. At the same time, there is a demand to shorten signal channel lengths for high frequency applications, to improve heat dissipation, improve robustness, and to decrease manufacturing costs.

The introduction of Ball Grid Arrays (BOA) and other array connect technologies in the last 10 years has enabled the semiconductor packaging industry to meet many of the demands. Still, there is an ongoing effort to improve the array connect technologies.

### SUMMARY

Accordingly, there is provided a semiconductor device comprising an array of contact elements soldered to only one surface, wherein the array defines a predetermined pitch length. The contact elements comprise a spherically shaped element and protrude from the only one surface by more than 60 percent of the predetermined pitch length.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A-1B schematically disclose an electronic device comprising an array of contact elements before, and after, soldering the electronic device to a carrier;

FIGS. 2A and 2B schematically disclose an embodiment of a semiconductor device as seen from the side and from the top.

FIG. 3A discloses an embodiment of a contact element before soldering it to a semiconductor device;

FIG. 3B discloses an embodiment of a section of an array of contact elements after having soldered the contact elements to a semiconductor device; and

FIG. 3C discloses an embodiment of a section of an array of contact elements after having soldered the contact elements to a semiconductor device and to a carrier.

### DETAILED DESCRIPTION

Although specific embodiments have been illustrated and described herein, it will be appreciated by those of ordinary skill in the art that a variety of alternate and/or equivalent implementations may be substituted for the specific embodiments shown and described without departing from the scope of the present invention. Generally, this application is intended to cover any adaptations or variations of the specific embodiments discussed herein. Therefore, it is intended that this invention be limited only by the claims and the equivalents thereof.

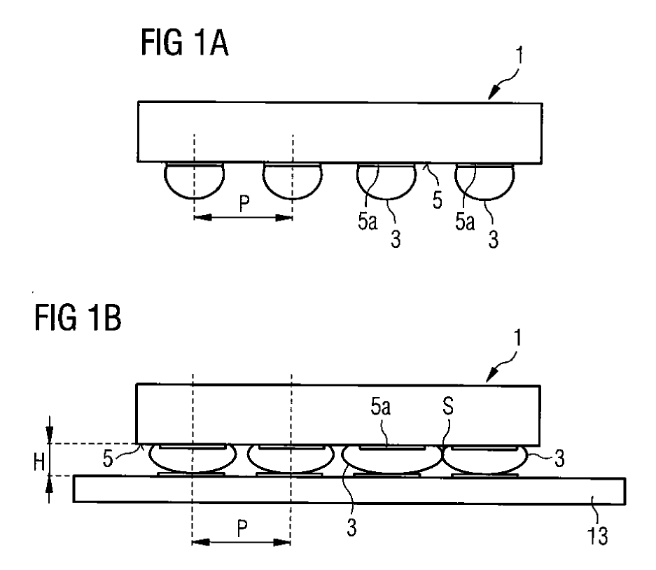

FIG. 1A discloses a side view of a conventional packaged semiconductor device I wherein an array of solder balls 3 is soldered to a pad surface 5a of surface 5 of semiconductor device 1. Each of the solder balls 3 represents an electronic input/output terminal to control an integrated circuit inside the packaged semiconductor device, or to receive signals from the integrated circuit. The provision of an array of contact elements makes it possible to place a large number of input/output terminals to the surface of a semiconductor device of a given size. With a high density of input/output terminals complex integrated circuits in small packages can be operated.

At the same time, the input/output terminal density is limited as decreasing the pitch length P of the array of input/output terminals may lead to a yield loss due to electric shorts between adjacent input/output terminals when soldered to a carrier. The reason is that the originally spherically shaped solder balls 3 may collapse in the soldering oven during manufacturing and during attachment of the semiconductor device 1 to an external carrier 13. For example, during application of the interconnect elements to the semiconductor device (first level assembly), the originally spherically shaped solder balls may stretch laterally in a direction towards adjacent solder balls, due to the wetting of the pad surface 5a of the semiconductor device in the soldering oven (see FIG. 1A). A further lateral stretching of the solder balls 3 may occur when during the soldering of the semiconductor device 1 to the external carrier 13, the solder balls 3 deform in the soldering oven under the weight of the semiconductor device. As a result, the distance between adjacent laterally expanded solder balls 3 becomes smaller so that electrical shorts S between them may occur (see FIG. 1B). Note that each lateral stretching also causes the stand-off height H, i.e. the distance between surface 5 of the semiconductor device and the external carrier 13, to become smaller.

Another way of increasing the input/output terminal density may be to reduce the size of the input/output terminals. However, this approach is hampered by the fact that smaller input/output terminals usually reduce the stand-off height H between carrier 13 and semiconductor device 1. A reduced stand-off height is less capable of absorbing lateral stress between the carrier 13 and the semiconductor device 1 that may be caused by different thermal expansions of the two during device operation. As a result, the input/output terminals 3 may break so that the electrical connection between carrier 13 and semiconductor device 1 is interrupted.

To best meet the requirements of high input/output density and good reliability, standards are used. For example, for input/output terminal arrays with a pitch of 500 micrometers, the solder balls with an original diameter of 300 micrometer are used. This size makes sure that after soldering the semiconductor device to a PCB, the diameters of the solder balls in lateral direction remain small enough to leave sufficient clearance between adjacent solder balls. At the same time a large stand-off height H is provided.

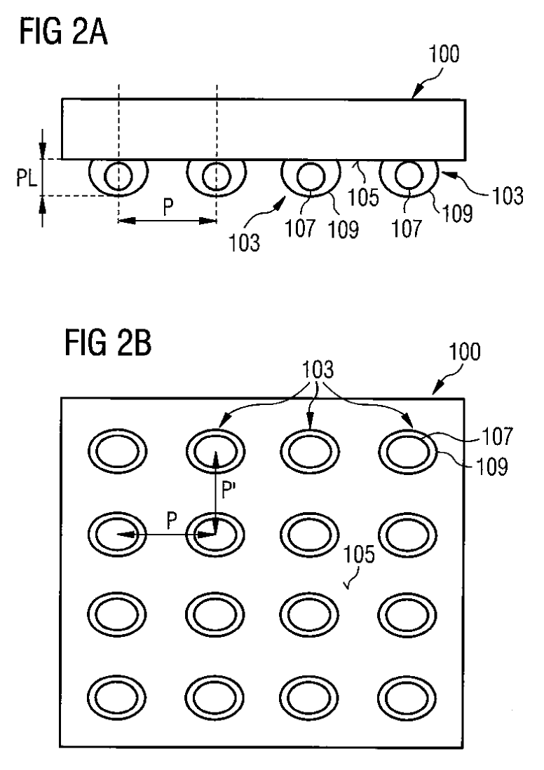

FIG. 2A and 2B schematically illustrate a side view and a top view of an embodiment wherein a semiconductor device 100 comprises an array of contact elements 103 soldered to only one surface 105. The array of contact elements 103 defines a first pitch P (predetermined pitch length) in a first direction, and a second pitch P′ in a second direction perpendicular to the first direction. In one embodiment, first pitch P is smaller, or equal, to second pitch P′.

FIG. 2A further illustrates that each of the contact elements 103 comprises a spherically shaped element 107. Further, each of the contact elements 103 protrudes from surface 105 by more than 60 percent of the predetermined pitch P, i.e. the ratio between protrusion length PL to first pitch P is larger than 0.6. The large protrusion length PL ensures a large stand-off height H when soldering the semiconductor device 100 to a carrier. A large stand-off height H helps absorbing lateral stress that may arise between the semiconductor device 100 and the carrier due to temperature cycles or mechanical shock. Contact elements that comprise spherically shaped elements and protrude from the surface by more than 60 percent of the pitch length have not been used before.

In one embodiment, each of the spherically shaped elements 107 is made of a core material (first material) that essentially maintains its shape when soldering the contact elements 103 to a surface. Therefore, with a heat-resistant spherically shaped element 107, collapsing of the contact elements 107 can be prevented when soldering the contact elements 107 to the surface of the semiconductor device 100, or to a carrier of the semiconductor device 100. This helps reducing the risk of adjacent contact elements touching each other when soldering the semiconductor device to a carrier.

In one embodiment, each of the spherically shaped elements 107 is at least partially covered a first layer 109 of a second material (see FIG. 2A and 2B). The second material may be an electrically conducting material, e.g. copper. In one embodiment, the second material may include, chrome, palladium, silver, titanium, gold, lead containing solder, tin containing solder, or an alloy of those materials. This way, the contact elements 103 are electrically conducting even if the spherically shaped elements 107 are made of an electrically insulating polymer.

In one embodiment, the contact elements 103 may include spherically shaped elements 107 that are covered by more than a first layer only. For example, each of the spherically shaped elements 107 may be at least partially covered by a first layer 109 of a second material, which in addition is least partially covered by a second layer of a third material and a third layer of a forth material. The second material may be an electrically conducting material, e.g. copper, chrome, palladium, silver, titanium, gold, a lead containing solder, a tin containing solder, or an alloy of those materials. The second layer may serve as a barrier layer for avoiding the building of intermetallic phases and the third layer for avoiding corrosion of the layers below, or providing a wettable surface for the solder material for second level assembly. Therefore the second layer may consist of, e. g., nickel while the third layer may consist of solder (e. g. SnAg, SnAgCu, SnPb) or a noble material (e. g. Au, Ag).

In one embodiment, the spherically shaped element 107 may be made of a polymer. Since a polymer element can maintain its shape during the soldering procedure, the cross section diameter of the contact elements 103 essentially does not expand laterally with respect to surface 5. This helps preventing undesired electrical shorts between adjacent contact elements 103 even when the contact elements 103 protrude from the surface by more than 60% of the first pitch P. Further, with the spherically shaped element 107 made of a polymer, the contact elements 107 may be sufficiently elastic to prevent that the contact elements 103 break from the carrier or from the surface 105 during thermal cycling or due to mechanical shocks.

In one embodiment, the first material of spherically shaped element 107 may be any other material that essentially maintains its shape during the soldering. For example, the first material may be copper, any other metal, ceramic, or organic.

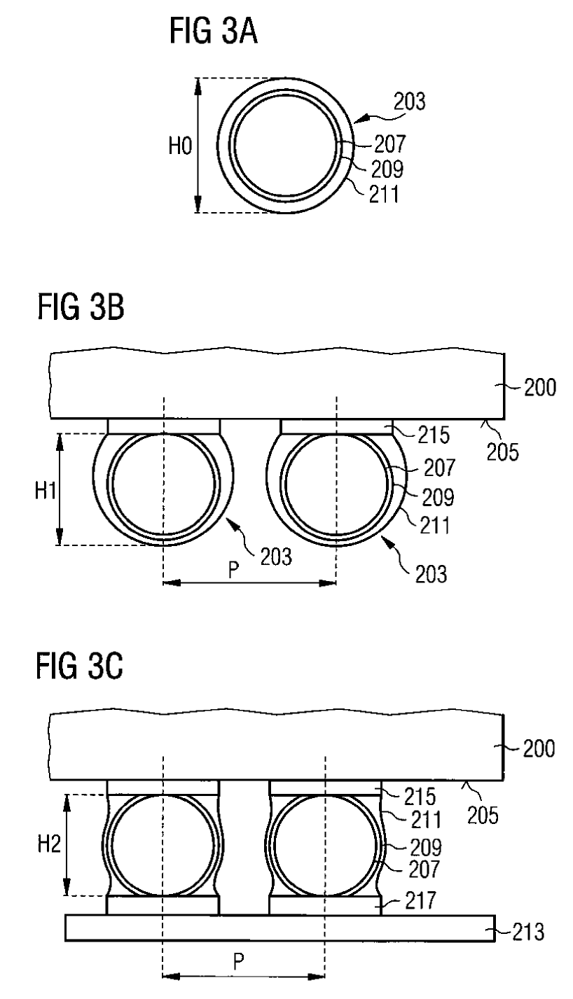

FIGS. 3A to 3C illustrate contact elements 203 at three different stages, i.e. (a) before soldering the contact elements 203 to a surface 205 of the semiconductor device 200 (FIG. 3A), (b) after having soldered the contact elements 203 to the surface 205 of the semiconductor device 200 and before soldering the contact elements 203 to a carrier 213 (FIG. 3B); and (c) after having soldered the contact elements 203 to a carrier 213 (FIG. 3C).

FIG. 3A illustrates an embodiment of a contact element 203 before it is soldered to a surface of a semiconductor device. Contact element 203 is spherically shaped (contact ball) having an original total diameter H0 of; say, 350 micrometer. It is comprised of a spherically shaped element 207, a first layer 209 covering the spherically shaped element 207, and a second layer 211 covering the first layer 209. In the following, the spherically shaped contact element 203 will also be referred to as “contact ball”.

In one embodiment, spherically shaped element 207 is made of a polymer, e.g. a high-heat resistant divinylbenzene cross-linked polymer. The spherical shape of the spherically shaped elements 207 helps manufacturing contact balls 203 that are spherically shaped as well. Spherically shaped contact balls 203 have the advantage that they can be attached to the surface of a semiconductor device by use of the well-known ball-apply process. The ball-apply process is a process where the contact balls are fed to the surface of a semiconductor device and, by use of a screen and a stencil or a screen/stencil and a solder ball transfer head, are attached to the semiconductor device at predetermined positions.

In FIG. 3A, spherically shaped element 207 is covered by first layer 209 made of an electrically conductive material, e.g. copper. In addition, first layer 209 is covered by a second layer 211 made of a solder material, e.g. an eutectic Sn/Pb solder, a Pb-free solder like Sn/Ag (96.5/3.5), Sn, or any other known solder material. Such contact balls may be purchased under the name “Micropearl SOL” by SEKISUI CHEMICAL CO.,LTD. The thickness of first layer 209 is typically in the range of one to a few micrometers up to a few ten micrometers. In one embodiment, the ratio of the thickness of the first layer to the diameter of the spherically shaped element is smaller than 1/10 to make sure that the elasticity of the contact element is warranted. In one embodiment, second layer 211 may serve as a solder depot used for soldering the contact element to the semiconductor device. In one embodiment, first layer 209 may serve as an electrical conductor to transport electric current from, say, a carrier to the integrated circuit in the semiconductor device. First layer 209 may also serve as a base material for applying the solder material for second layer 211.

The thickness of second layer 211 is typically in the range of one to a few micrometers up to a few ten micrometers. In one embodiment, the ratio of the thickness of the second layer to the diameter of the spherically shaped element is smaller than 1/10 to keep the deformation of the contact element small during soldering. In one embodiment, second layer 211 serves as a solder depot used for soldering the contact ball to the surface of the semiconductor device, or for soldering the contact ball to a carrier. Before soldering the contact element, typically, spherically shaped element 207, first layer 209 and second layer 211 are concentrically aligned to each other for the contact element 203 to have an essentially spherical shape. Further, the thicknesses of first and second layers 209, 211 are small in comparison to the diameter of the spherically shaped elements 207. For example, for a contact ball having an original diameter of 350 micrometers, the sum of the first and second layer thicknesses may be only a few ten micrometers.

FIG. 3B illustrates a section of an embodiment wherein an array of contact balls 203 has been soldered to a surface 205 of a semiconductor device 200. For illustrational purposes, only a section of the semiconductor device 200 with only two contact balls is shown. The two contact element 203 are part of a two-dimensional array of contact elements having a pitch P. Pitch P of the array is such that the ratio of contact ball diameter H0 to pitch P is larger than 0.6. For example, if the pitch of the array is 500 micrometer the contact ball diameter H0 may be 350 micrometer; if the pitch of the array is 400 micrometer, the contact ball diameter H0 may be 250 micrometer; if the pitch of the array is 300 micrometer, the contact ball diameter H0 may be 180 micrometer. The large contact ball diameters make sure that the stand-off height H2 (see FIG. 3C) between the semiconductor device 200 and a carrier 213 of the semiconductor device is large in comparison to known semiconductor devices. At the same time, due to the spherically shaped element that prevents the contact ball to collapse during the soldering procedure, the risk of electric shorts between adjacent contact balls is low.

As can be seen in FIG. 3B, the contact balls 203 are soldered to contact pads 215 that are part of surface 205. Due to the wetting of the contact pad 215 with the solder material of second layer 211 of the contact balls 203 during the soldering, the shape of contact ball 213 is slightly distorted. Still, in view that the diameter of spherically shaped element 207 is significantly larger than the thicknesses of the first and second layers 209, 211 covering the spherically shaped elements 207, the protrusion length H1 defined by the distance between contact pad 215 and the most distant point of contact ball 203 in a direction perpendicular to the surface 215 remains of essentially the same size as the contact ball diameter H0 before the soldering (see FIG. 3A).

The soldering of the contact balls to the semiconductor device 200 can be carried out in many different ways. Further, the contact balls can be applied to a semiconductor wafer (Wafer Level Packaging), to a packaged chip, or to a chip array embedded in a packaging material (embedded Wafer Level Packaging). If applying the contact balls to a wafer, a typical procedure is, first, to selectively apply flux to the wafer at the interconnect sites via screen-printing. Afterwards, a metal stencil is applied to the wafer. The stencil has an array of openings for receiving and attaching the contact balls to the various flux locations. It follows a step where the contact balls are fed to the stencil surface while moving a contact ball transfer head over the stencil surface. The movement of the transfer head over the stencil distributes the spherically shaped contact balls over the stencil surface with the effect that contact balls that reach a stencil opening site are received by the opening to get in contact with the flux element on the wafer. Once all stencil openings are each filled with a contact ball, the stencil can be removed. In a next step, the wafer is introduced into an oven to start the activation if the assembly partners by the flux and to melt the solder material of the contact balls. The melted solder material wets the surface of the wafer such that, after cool down, the contact balls are Firmly soldered to the wafer.

FIG. 3C illustrates section of the semiconductor device 200 after having it soldered to a carrier 213. Carrier 213 may be a printed circuit board (PCB), a ceramic, an interposer or any other board that can be used for carrying a chip or semiconductor device. Typically, carrier 213 comprises leads and contact pads 217 to receive the contact balls 213.

As can be seen from FIG. 3C, for soldering semiconductor device 200 to carrier 213, semiconductor device 200 has been heated such that the solder material of second layer 21 1 melts to wet contact pad 217 of carrier 213. Due to the heat-resistant spherical shaped element 207, the shape of contact ball 203 essentially remains. As a result, the stand-off height H2 defined by the distance between the two contact pads 215, 217 does not shrink significantly. As a consequence, also the ratio of the stand-off height H2 to the pitch length P is larger than 0.6.

What is claimed is:

1. A semiconductor device comprising:
an array of contact elements soldered to only one surface, the array defining a predetermined pitch length;
wherein the contact elements comprise a spherically shaped element; and
wherein the contact elements protrude from the only one surface by more than 60 percent of the predetermined pitch length.

2. The semiconductor device according to claim 1 wherein each of the spherically shaped elements is comprised of a first material.

3. The semiconductor device according to claim 2 wherein the first material comprises at least one of a polymer, a ceramic, a metal and an organic material.

4. The semiconductor device according to claim 1 wherein each of the spherically shaped elements is at least partly covered by a first layer of a second material.

5. The semiconductor device according to claim 4 wherein the second material comprises at least one of nickel, lead containing solder, tin containing solder, copper, chrome, palladium, silver, titanium, gold and an alloy thereof.

6. The semiconductor device according to claim 4 wherein the first layer is at least partly covered by a second layer of a third material.

7. The semiconductor device according to claim 4 wherein the first layer is at least partly covered by a second layer of a third material and the second layer is at least partly covered by a third layer of a forth material.

8. The semiconductor device according to claim 6 wherein the third material comprises at least one of nickel, lead containing solder, tin containing solder, copper, chrome, palladium, silver, titanium, gold and an alloy thereof.

9. The semiconductor device according to claim 6 wherein the forth material comprises at least one of nickel, lead containing solder, tin containing solder, copper, chrome, palladium, silver, titanium, gold and an alloy thereof.

10. The semiconductor device according to claim 4 wherein the ratio of the thickness of the first layer to the diameter of the spherically shaped element is smaller than 1/10.

11. The semiconductor device according to claim 6 wherein the ratio of the thickness of the second layer to the diameter of the spherically shaped element is smaller than 1/10.

12. The semiconductor device according to claim 1 wherein the diameter of the spherically shaped elements is larger than 60% of the predetermined pitch length.

13. The semiconductor device according to claim 1 further comprising a semiconductor chip electrically coupled to the contact elements.

14. The semiconductor device according to claim 1 wherein the array of of contact elements is a two-dimensional array.

15. A semiconductor device comprising:
an array of contact elements soldered to only one surface, the array defining a predetermined pitch length;
wherein each of the contact elements comprises a spherically shaped element, each spherically shaped element having a diameter larger than 60 percent of the predetermined pitch length.
